(19) United States
(12) Patent Application Publication
(10) Pub. No.: US 2025/0311284 A1
(43) Pub. Date: Oct. 2, 2025

(54) SEMICONDUCTOR DEVICES WITH ALTERNATING INSULATING LAYERS AND METHODS OF FABRICATION THEREOF

(71) Applicant: TEXAS INSTRUMENTS INCORPORATED, Dallas, TX (US)

(72) Inventors: Casey Hopper, Richardson, TX (US); Archana Venugopal, Mountain View, CA (US)

(21) Appl. No.: 18/620,887

(22) Filed: Mar. 28, 2024

(51) Int. Cl. H01L 29/78; H01L 29/08; H01L 29/423; H01L 29/66

(52) U.S. Cl. CPC H10D 30/65; H10D 30/0221; H10D 30/0281; H10D 30/603; H10D 62/151; H10D 64/516

(57) ABSTRACT

Semiconductor devices and fabrication methods thereof are described. For example, a semiconductor device includes a semiconductor layer, a drain region disposed in the semiconductor layer, a source region disposed in the semiconductor layer, a channel region disposed between the drain region and the source region, a gate disposed over the channel region, and first and second insulating layers disposed between the gate and the semiconductor layer. Sections of the first insulating layer and sections of the second insulating layer alternate along a first direction perpendicular to a second direction defined between the drain region and the source region, each of the sections of the first insulating layer having a first thickness and each of the sections of the second insulating layer having a second thickness greater than the first thickness.

### TECHNICAL FIELD

The present disclosure relates to the field of semiconductor transistors, and more particularly, but not exclusively, to laterally diffused metal oxide semiconductor (LDMOS) transistors.

### BACKGROUND

LDMOS devices are field-effect transistors (FETs) designed for high power applications. In an LDMOS device, the drain and source have a relatively large spacing between them, as compared with MOS devices designed for other applications, and lateral diffusions are used to produce a well-controlled channel region under the gate. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with alternating gate insulating layers and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a semiconductor layer, a drain region disposed in the semiconductor layer, a source region disposed in the semiconductor layer, a channel region disposed between the drain region and the source region, a gate disposed over the channel region, and first and second insulating layers disposed between the gate and the semiconductor layer. Sections of the first insulating layer and sections of the second insulating layer alternate along a first direction perpendicular to a second direction defined between the drain region and the source region, each of the sections of the first insulating layer having a first thickness and each of the sections of the second insulating layer having a second thickness greater than the first thickness.

In some other examples, a semiconductor device includes a semiconductor layer, a drain region disposed in the semiconductor layer, a source region disposed in the semiconductor layer, a channel region disposed between the drain region and the source region, a gate disposed over the channel region, and gate dielectric and field dielectric layers disposed between the gate and the semiconductor layer. Sections of the gate dielectric layer and sections of the field dielectric layer alternate along a first direction perpendicular to a second direction defined between the drain region and the source region, each of the sections of the gate dielectric layer having a first thickness and each of the sections of the field dielectric layer having a second thickness greater than the first thickness.

In some additional examples, a method of fabricating a semiconductor device includes forming a semiconductor layer, forming a drain region in the semiconductor layer, forming a source region in the semiconductor layer, forming a channel region between the drain region and the source region, and forming first and second insulating layers at least partially along the channel region and between the drain region and the source region. Sections of the first insulating layer and sections of the second insulating layer alternate along a first direction perpendicular to a second direction defined between the drain region and the source region, each of the sections of the first insulating layer having a first thickness and each of the sections of the second insulating layer having a second thickness greater than the first thickness. The method further includes forming a gate on the first and second insulating layers.

### BRIEF DESCRIPTION OF THE DRAWINGS

FIG. 1A is a top view of a semiconductor device in accordance with examples of the present disclosure;

FIGS. 1B through 1D are cross-sectional views of the semiconductor device of FIG. 1A;

FIG. 1E is a three-dimensional view of a portion of the semiconductor device of FIG. 1A;

FIG. 2A is a top view of a semiconductor device in accordance with other examples of the present disclosure;

FIGS. 2B through 2D are cross-sectional views of the semiconductor device of FIG. 2A;

FIG. 2E is a three-dimensional view of a portion of the semiconductor device of FIG. 2A;

FIG. 3A is a top view of a semiconductor device in accordance with further examples of the present disclosure;

FIGS. 3B through 3E are cross-sectional views of the semiconductor device of FIG. 3A;

FIG. 3F is a three-dimensional view of a portion of the semiconductor device of FIG. 3A;

FIGS. 4A-4G are cross-sectional views of a first process flow for forming sections of a field dielectric layer of a semiconductor device in accordance with examples of the present disclosure;

FIGS. 5A-5G are cross-sectional views of a second process flow for forming sections of a field dielectric layer of a semiconductor device in accordance with examples of the present disclosure; and

FIGS. 6A-6I are cross-sectional views of a third process flow for forming sections of a field dielectric layer of a semiconductor device in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean+/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) parameter and a breakdown voltage (BV) parameter. For example, design approaches that seek to achieve the advantage of a higher BV by increasing the body area of the device consequently lead to the disadvantage of a higher Rsp. Similarly, design approaches that seek to decrease Rsp generally come at the cost of decreasing the BV rating. Accordingly, LDMOS design approaches that effectively manage this tradeoff provide technical advantages.

Semiconductor devices, such as LDMOS devices, are described herein which allow for a relatively large decrease in Rsp without a significant loss in the BV rating. In some examples, this and other technical advantages may be achieved by interdigitating or alternating first and second insulating layers having different thicknesses between a gate and a semiconductor layer of a semiconductor device in a first direction (e.g., a channel width direction) which is perpendicular to a second direction (e.g., a channel length direction) defined between the source and drain regions of the semiconductor device. Sections of the first insulating layer having a first thickness are interdigitated or alternated with sections of the second insulating layer having a second thickness greater than the first thickness. The first insulating layer having the first thickness may be referred to herein as a gate insulator (e.g., a gate dielectric layer), while the second insulating layer having the second thickness may be referred to herein as a field insulator or a step-dielectric layer (e.g., a field dielectric layer, a field relief layer).

In some examples, shallow trench isolation (STI) regions (or local oxidation of silicon (LOCOS) regions) are formed in the semiconductor layer in the areas where the sections of first insulating layer having the first thickness are formed. The interdigitated STI regions (or LOCOS regions) provide isolation (or mitigate electric field effect) which aids in BV retention. The areas where the sections of the second insulating layer having the second thickness are formed (e.g., step-dielectric regions) allow for reducing Rsp relative to the areas where the sections of the first insulating layer and the STI regions are formed. Current flows laterally from the drain region to the source region under the gate. The STI regions contribute to increased Rsp, e.g., since the current flows around the STI regions formed in the semiconductor layer. However, the step-dielectric regions (e.g., where the STI regions are not formed) contribute to lower Rsp, e.g., since the current flows more directly from the drain region to the source region through the step-dielectric regions.

In other examples, STI regions are not formed in the semiconductor layer in the areas where the sections of the first insulating layer having the first thickness are formed. Thus, the areas where the sections of the first insulating layer having the first thickness are formed have decreased Rsp relative to the step-dielectric regions which have increased Rsp. Such structures, however, have a lower BV compared with structures that utilize STI regions in the areas where the sections of the first insulating layer having the first thickness are formed. In other examples, the gate may be recessed (e.g., such that the gate terminates farther from the drain region) in the areas where the sections of the first insulating layer having the first thickness are formed. This allows for some recovery of the BV relative to structures without the recessed gate.

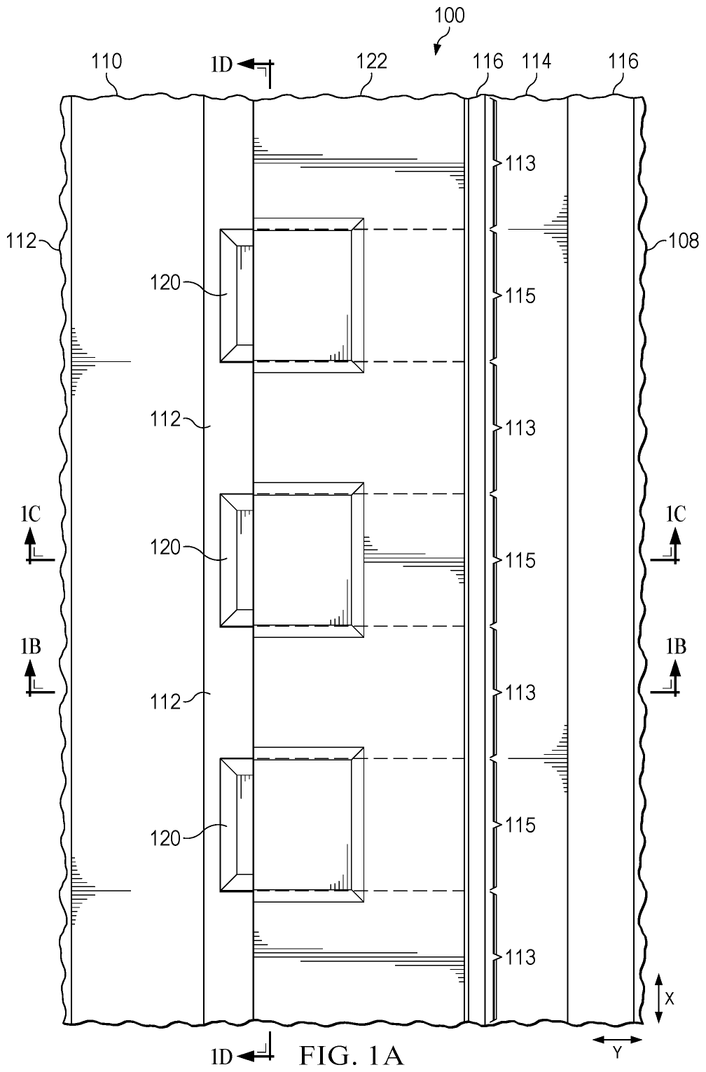

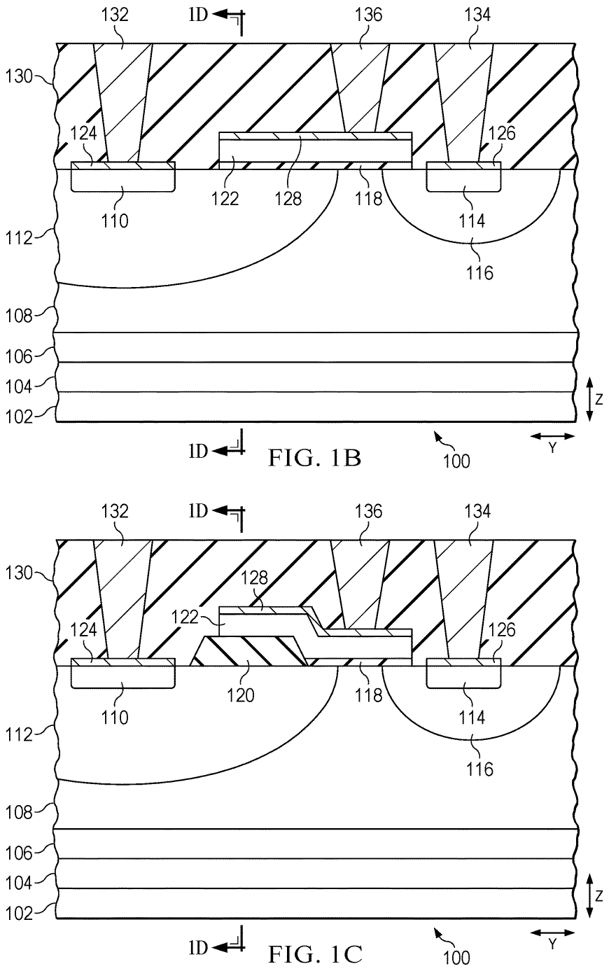

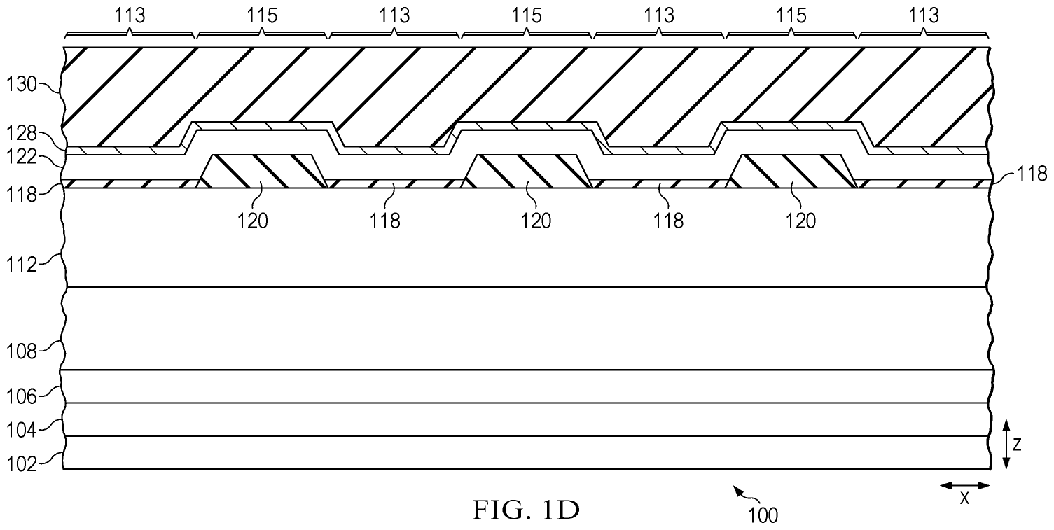

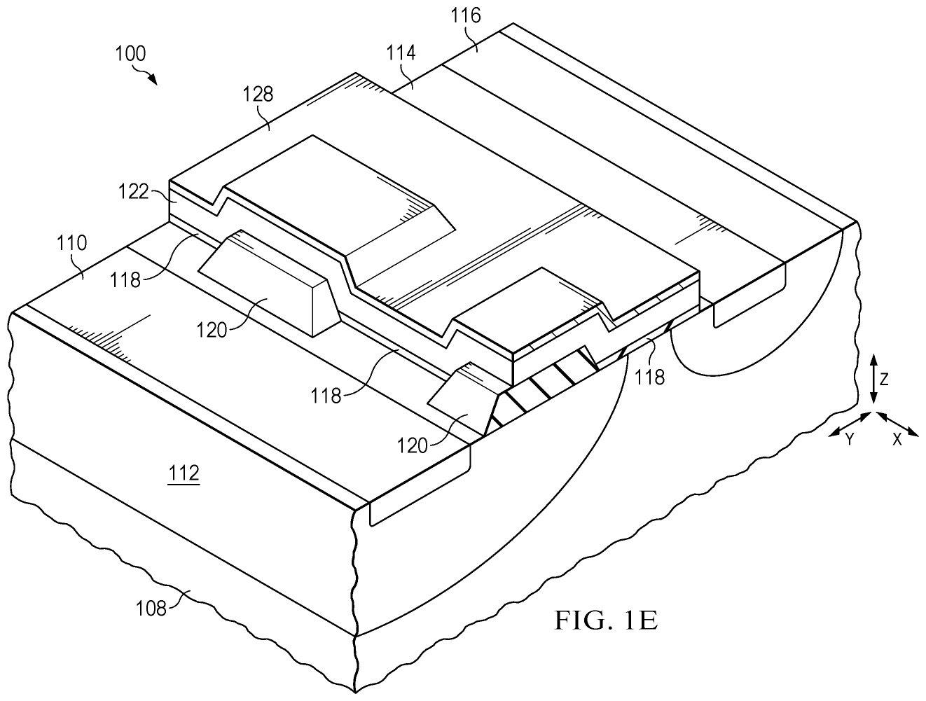

Referring now to FIG. 1A, a top view of an LDMOS device 100 is shown. The LDMOS device 100 includes a drain region 110, a source region 114, and a gate 122. In a first direction (direction X, e.g., channel width direction) along the gate 122, which is perpendicular to a second direction (direction Y, e.g., channel length direction) defined between the drain region 110 and the source region 114, there are alternating regions 113 and 115. The regions 113 are where a step-dielectric or field insulator is not formed and the regions 115 are where a step-dielectric or field insulator is formed. In the description below, the regions 113 will be referred to as non-step-dielectric regions 113 while the regions 115 will be referred to as step-dielectric regions 115.

FIG. 1A shows each of the regions 113 and 115 having a same width in the first direction (direction X) by way of example only. In other examples, the non-step-dielectric regions 113 are wider in the first direction (direction X) than the step-dielectric regions 115. In still other examples, the step-dielectric regions 115 are wider in the first direction (direction X) than the non-step-dielectric regions 113. Further, different ones of the non-step-dielectric regions 113 and/or the step-dielectric regions 115 may have different widths in the first direction (direction X), e.g., a first one of the non-step-dielectric regions 113 is wider than a second one of the non-step-dielectric regions 113, or a first one of the step-dielectric regions 115 is wider than a second one of the step-dielectric regions 115, combinations thereof, etc. Additional features of the LDMOS device 100 shown in FIG. 1A, as well as some features not expressly shown, are described below.

FIG. 1B shows a first cross-sectional view of the LDMOS device 100 taken along the cut line shown in FIG. 1A in the second direction (direction Y) across one of the non-step-dielectric regions 113. FIG. 1C shows a second cross-sectional view of the LDMOS device 100 taken along the cut line shown in FIG. 1A in the second direction (direction Y) across one of the step-dielectric regions 115. FIG. 1D shows a third cross-sectional view of the LDMOS device 100 taken along the cut line shown in FIG. 1A in the first direction (direction X) along the gate 122.

As shown in FIG. 1B, the LDMOS device 100 includes a substrate 102, a first buried layer 104, a second buried layer 106, and a semiconductor layer 108, e.g., formed by an epitaxial process in some examples, thus an epi layer 108 in such examples. A drain region 110 and a drain drift region 112 are disposed in the epi layer 108. A well region 116 is also disposed in the epi layer 108, and a source region 114 is disposed in the well region 116. A channel region may be considered to extend across a portion of epi layer 108 under gate 122 between the drain region 110 and the source region 114.

In some examples, the substrate 102, the second buried layer 106, the epi layer 108 and the well region 116 have a first conductivity (e.g., one of p-type and n-type), while the first buried layer 104, drain region 110, drain drift region 112 and source region 114 have a second conductivity (e.g., the other of p-type and n-type). While two buried layers, e.g., the first buried layer 104 and the second buried layer 106, are shown, other examples may include one or the other of the buried layers, or no buried layer at all.

A first insulating layer 118 having a first thickness (in direction Z) is disposed between the gate 122 and underlying portions of the drain drift region 112, the epi layer 108, and the well region 116. The first insulating layer 118 may be referred to as a gate dielectric or a gate insulator.

As shown in FIG. 1C, a second insulating layer 120 having a second thickness (in direction Z) different than the first thickness is disposed between a portion of the gate 122 and underlying portions of the drain drift region 112. The second insulating layer 120 may be referred to as a step dielectric of a field insulator.

In some examples, the first thickness of the first insulating layer 118 may be in a range between 3 nanometers (nm) and 15 nm, and the second thickness of the second insulating layer 120 may be in a range between 50 nm and 150 nm. In other examples, the thickness ranges of the first and second insulating layers 118 and 120 may vary from the above example with the thickness of the second insulating layer 120 being greater than the thickness of the first insulating layer 118.

As shown in FIG. 1D, sections of the first insulating layer 118 and the second insulating layer 120 alternate in the first direction (direction X) in the non-step-dielectric regions 113 and the step-dielectric regions 115. Thus, in the step-dielectric region 115, a portion of the gate 122 is farther from the underlying drain drift region 112 (in direction Z).

In some examples, the first insulating layer 118 and the second insulating layer 120 are formed of a same material, such as an oxide material. In other examples, the first insulating layer 118 and the second insulating layer 120 are formed of different materials, such as the first insulating layer 118 being an oxide material and the second insulating layer 120 being a nitride material or a multi-layer configuration including an interfacial oxide and a nitride material. In other examples, the first insulating layer 118 and the second insulating layer 120 are different oxide materials, etc.

The gate 122 is disposed over the first insulating layer 118 and at least a portion of the second insulating layer 120, e.g., as depicted in FIGS. 1C and 1D. In some examples, the gate 122 is a polysilicon material. In other examples, the gate 122 is a metal or other suitable material. The gate 122, as will be discussed in further detail below, may be conformally deposited over the first insulating layer 118 and at least a portion of the second insulating layer 120 such that the gate 122 has a uniform thickness. As shown in FIG. 1C, the gate 122 extends in the second direction (direction Y) and is disposed over only a portion of the second insulating layer 120. In other examples, however, the gate 122 extends further in the second direction (direction Y) to an edge of the second insulating layer 120 closest to the drain region 110, such as up to a beginning of the tapered sidewalls of the second insulating layer 120 or covering at least a portion of the tapered sidewalls of the second insulating layer 120. In some examples, the gate 122 extends less in the second direction (direction Y) than that shown in FIG. 1C, such that the gate 122 terminates further from the edge of the second insulating layer 120 that is closest to the drain region 110.

Silicide layers 124, 126 and 128 are disposed in contact with the drain region 110, the source region 114 and the gate 122, respectively. The silicide layers 124, 126 and 128 provide ohmic contacts and high conductivity.

An interlayer dielectric (ILD) 130 is disposed over the structure, and conductive vias 132, 134 and 136 are disposed in the ILD 130 to contact the silicide layers 124, 126 and 128, respectively.

FIG. 1E shows a three-dimensional view of a portion of the LDMOS device 100. More particularly, FIG. 1E is a three-dimensional view from the perspective of a portion of the cross-sectional view of FIG. 1D without the ILD 130 shown.

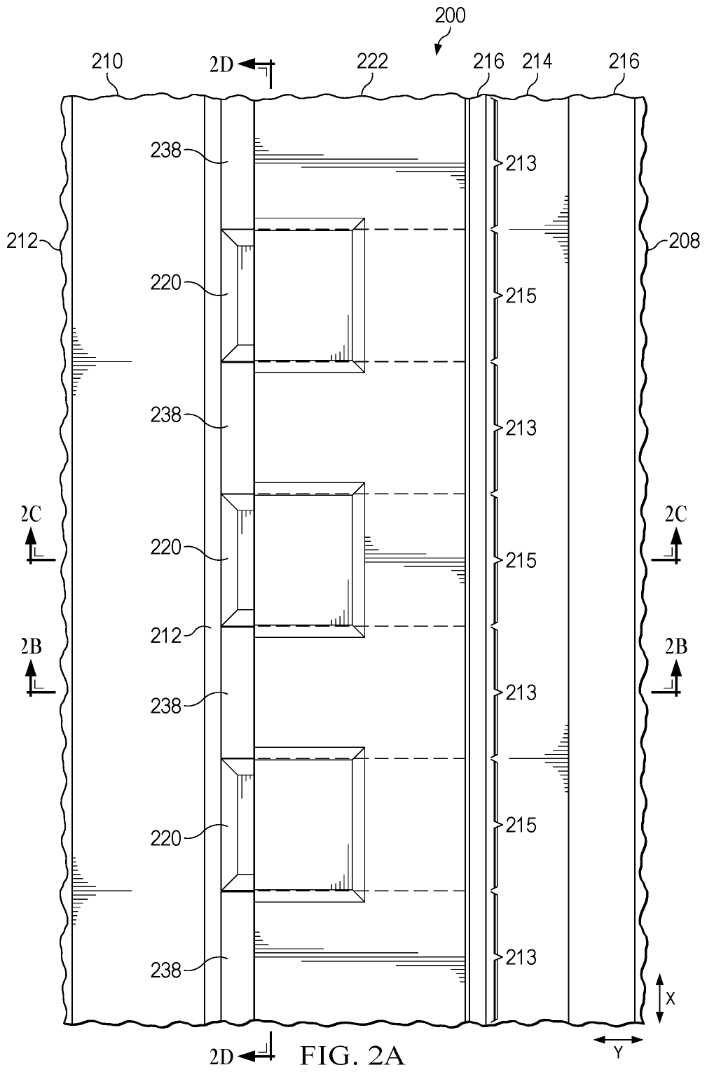

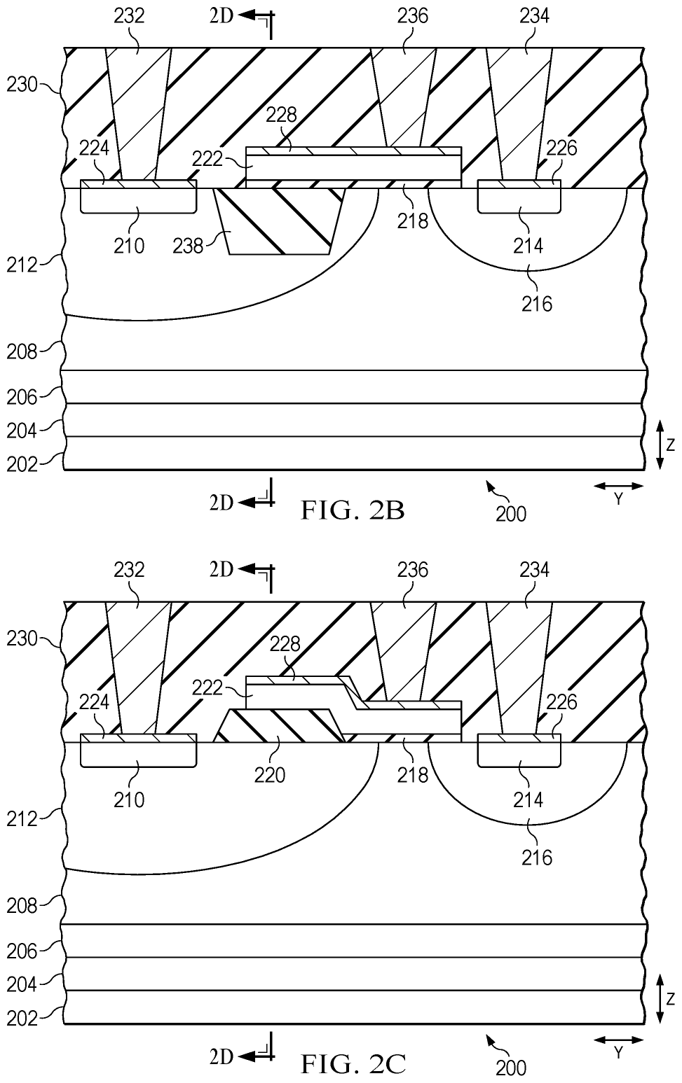

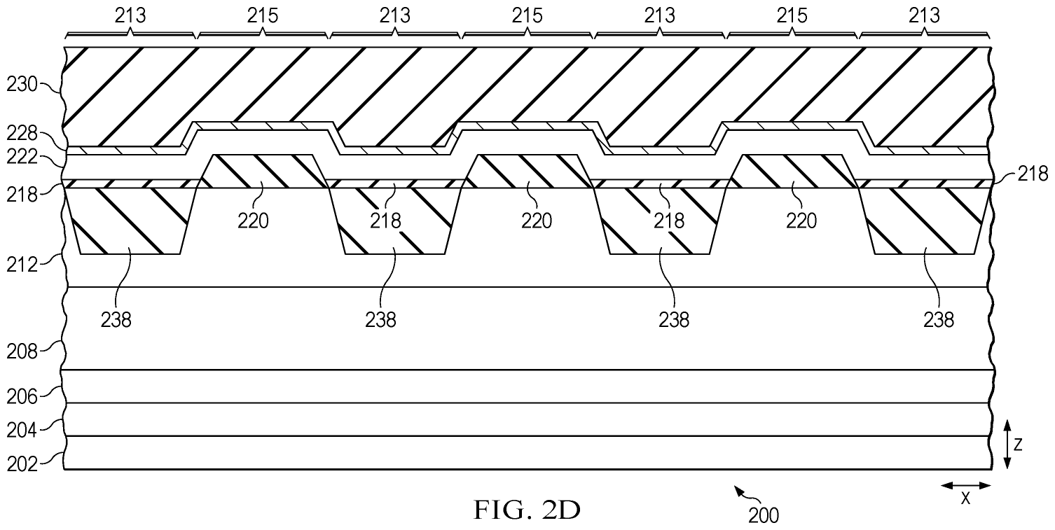

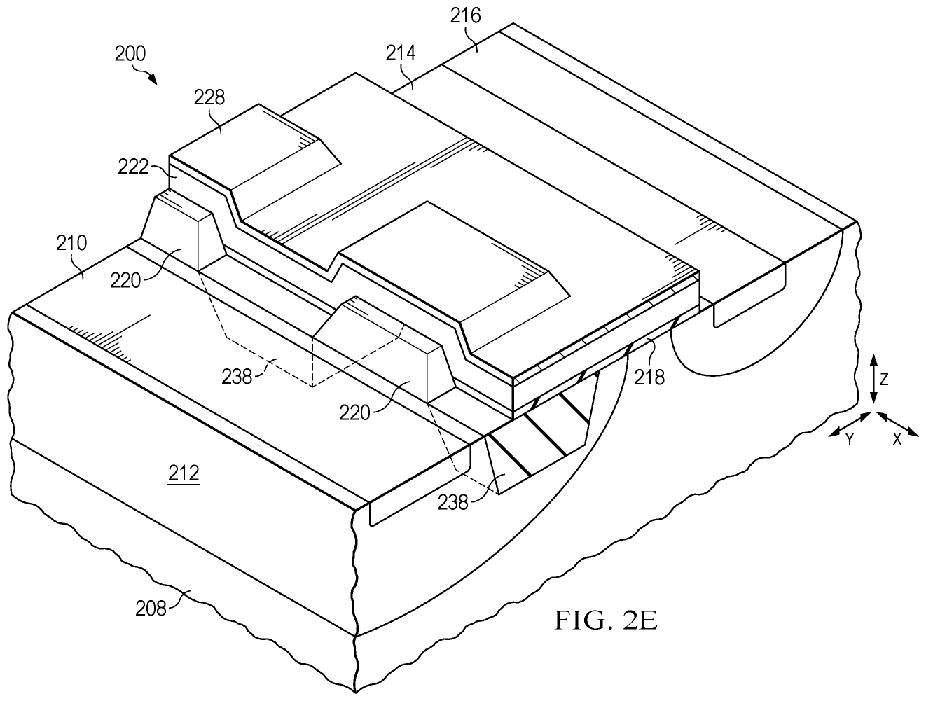

Referring now to FIG. 2A, a top view of an LDMOS device 200 is shown. The LDMOS device 200 includes a drain region 210, a source region 214, and a gate 222. In a first direction (direction X, e.g., a channel width direction) along the gate 222, which is perpendicular to a second direction (direction Y, e.g., a channel length direction) defined between the drain region 210 and the source region 214, there are alternating regions 213 and 215. The regions 213 are where a step-dielectric or field insulator is not formed and where STI regions 238 (or LOCOS regions in some examples) are formed, and the regions 215 are where a step-dielectric or field insulator is formed. In the description below, the regions 213 will be referred to as non-step-dielectric regions 213 while the regions 215 will be referred to as step-dielectric regions 215.

FIG. 2A shows each of the regions 213 and 215 having a same width in the first direction (direction X) by way of example only. In other examples, the non-step-dielectric regions 213 are wider in the first direction (direction X) than the step-dielectric regions 215. In still other examples, the step-dielectric regions 215 are wider in the first direction (direction X) than the non-step-dielectric regions 213. Further, different ones of the non-step-dielectric regions 213 and/or the step-dielectric regions 215 may have different widths in the first direction (direction X), e.g., a first one of the non-step-dielectric regions 213 is wider in the first direction (direction X) than a second one of the non-step-dielectric regions 213, a first one of the step-dielectric regions 215 is wider in the first direction (direction X) than a second one of the step-dielectric regions 215, combinations thereof, etc. Additional features of the LDMOS device 200 shown in FIG. 2A, as well as some features not expressly shown, are described below.

FIG. 2B shows a first cross-sectional view of the LDMOS device 200 taken along the cut line shown in FIG. 2A in the second direction (direction Y) across one of the non-step-dielectric regions 213 where one of the STI regions 238 is formed. FIG. 2C shows a second cross-sectional view of the LDMOS device 200 taken along the cut line shown in FIG. 2A in the second direction (direction Y) across one of the step-dielectric regions 215. FIG. 2D shows a third cross-sectional view of the LDMOS device 200 taken along the cut line shown in FIG. 2A in the first direction (direction X) along the gate 222.

The LDMOS device 200 includes a substrate 202, a first buried layer 204, a second buried layer 206, a semiconductor layer 208 (or an epi layer 208), the drain region 210, a drain drift region 212, the source region 214, a well region 216, a first insulator layer 218, a second insulator layer 220, the gate 222, silicide layers 224, 226 and 228, ILD 230, and conductive vias 232, 234 and 236 which are disposed in a manner similar to that described above with respect to the substrate 102, the first buried layer 104, the second buried layer 106, the epi layer 108, the drain region 110, the drain drift region 112, the source region 114, the well region 116, the first insulator layer 118, the second insulator layer 120, the gate 122, the silicide layers 124, 126 and 128, the ILD 130, and the conductive vias 132, 134 and 136 of the LDMOS device 100. A channel region may be considered to extend across a portion of the epi layer 208 under gate 222 between the drain region 210 and the source region 214. While two buried layers, e.g., the first buried layer 204 and the second buried layer 206, are shown, other examples may include one or the other of the buried layers, or no buried layer at all.

The LDMOS device 200, as shown in FIGS. 2A, 2B and 2D, includes the STI regions 238 in the non-step-dielectric regions 213. The STI regions 238 are formed of an insulating material, which may be the same as or different than the insulating or dielectric material used for the first insulating layer 218 and/or the second insulating layer 220. The STI regions 238 are disposed in the drain drift region 212. The STI regions 238 extend in the second direction (direction Y) from a first edge of the drain region 210 towards the well region 216, such that at least a portion of the gate 222 is disposed over at least a portion of the STI regions 238.

FIG. 2E shows a three-dimensional view of a portion of the LDMOS device 200. More particularly, FIG. 2E is a three-dimensional view from the perspective of a portion of the cross-sectional view of FIG. 2D without the ILD 230 shown.

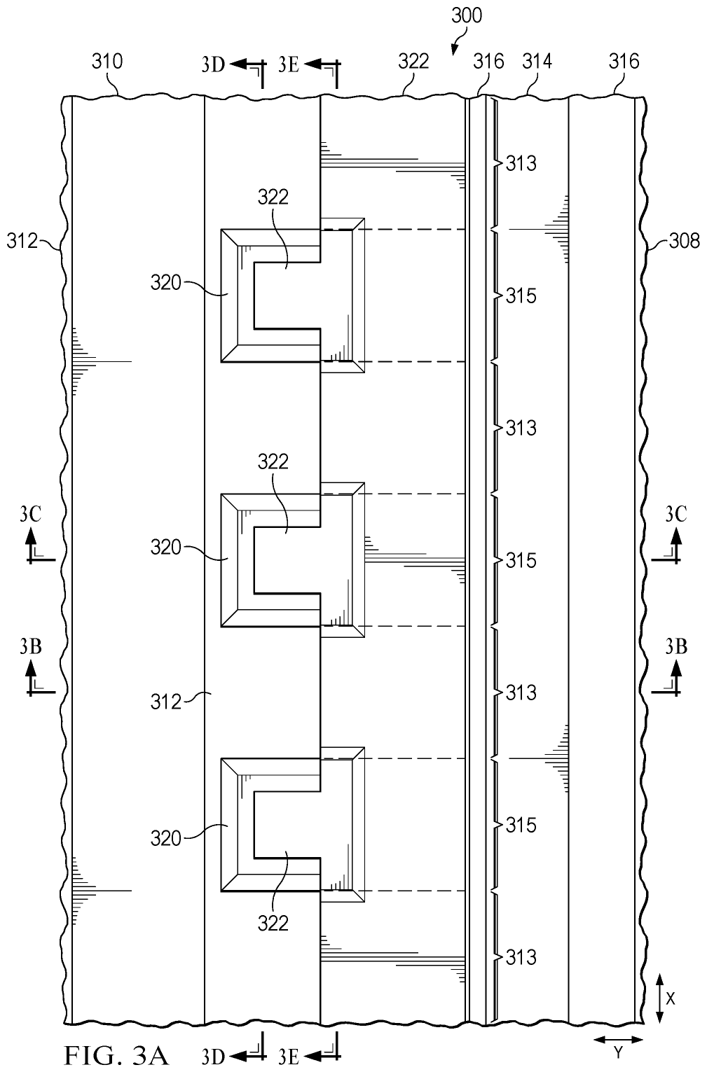

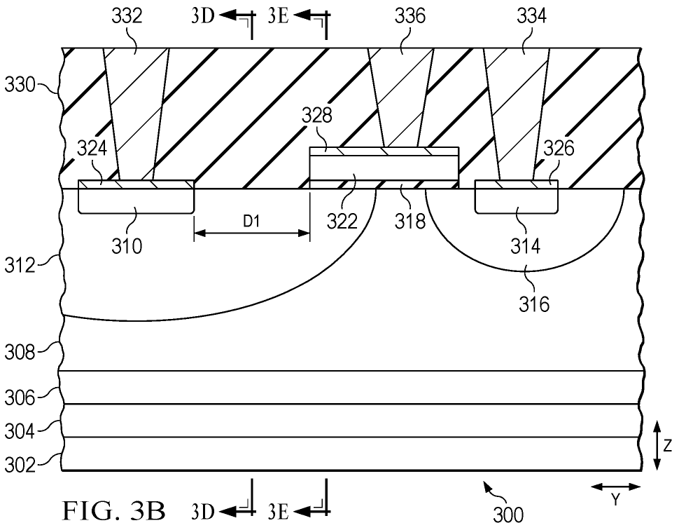

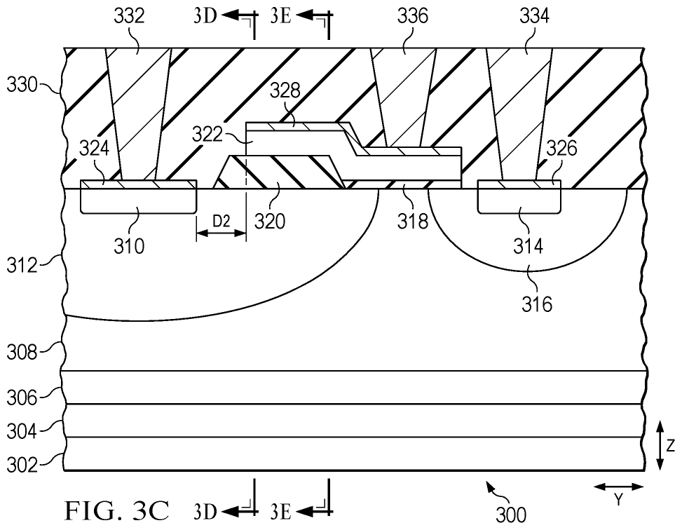

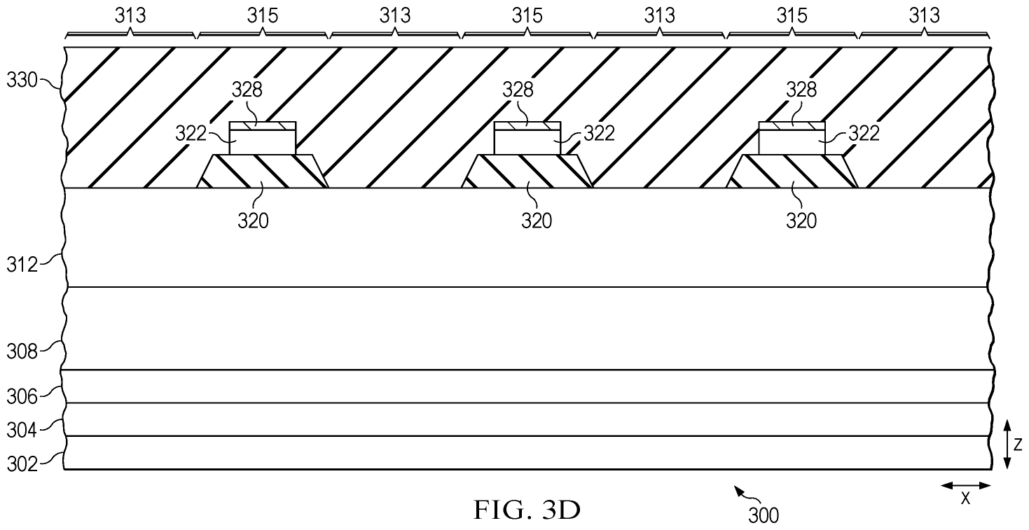

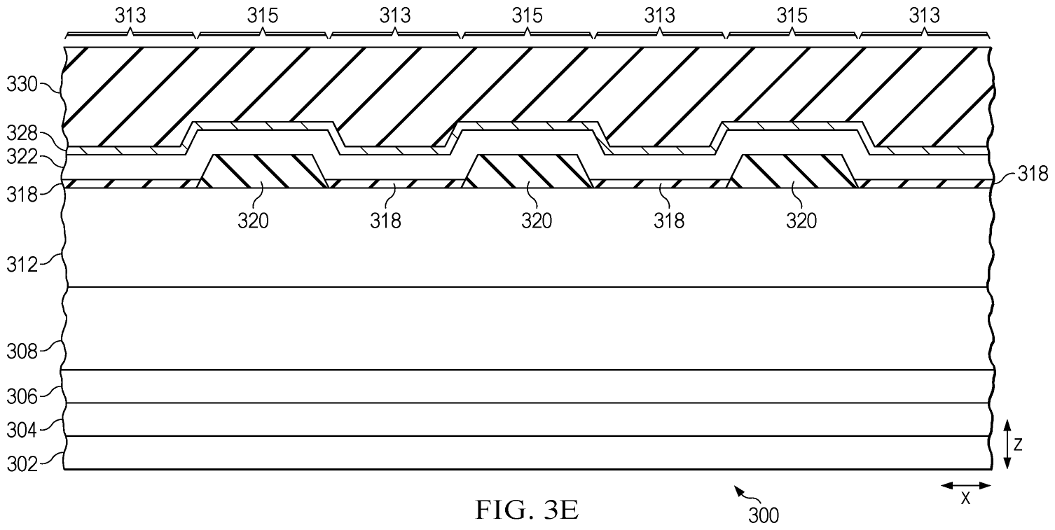

Referring now to FIG. 3A, a top view of an LDMOS device 300 is shown. The LDMOS device 300 includes a drain region 310, a source region 314, and a gate 322. In a first direction (direction X, e.g., a channel width direction) along the gate 322, which is perpendicular to a second direction (direction Y, e.g., a channel length direction) defined between the drain region 310 and the source region 314, there are alternating regions 313 and 315. The regions 313 are where a step-dielectric is not formed and where the gate 322 is recessed in the second direction (direction Y) away from the drain region 310, and the regions 315 are where a step-dielectric is formed and where the gate 322 is not recessed away from the drain region 310. In the description below, the regions 313 will be referred to as non-step-dielectric regions 313 while the regions 315 will be referred to as step-dielectric regions 315.

FIG. 3A shows each of the regions 313 and 315 having a same width in the first direction (direction X) by way of example only. In other examples, the non-step-dielectric regions 313 are wider in the first direction (direction X) than the step-dielectric regions 315. In still other examples, the step-dielectric regions 315 are wider in the first direction (direction X) than the non-step-dielectric regions 313. Further, different ones of the non-step-dielectric regions 313 and/or the step-dielectric regions 315 may have different widths in the first direction (direction X), e.g., a first one of the non-step-dielectric regions 313 is wider in the first direction (direction X) than a second one of the non-step-dielectric regions 313, a first one of the step-dielectric regions 315 is wider in the first direction (direction X) than a second one of the step-dielectric regions 315, combinations thereof, etc.

Further, in some examples, an amount of the recess of the gate 322 in the second direction (direction Y) varies between different ones of the non-step-dielectric regions 313. Thus, in a first one of the non-step-dielectric regions 313, the gate 322 may be recessed a first distance in the second direction (direction Y) away from the drain region 310, while in a second one of the non-step-dielectric regions 313 the gate 322 may be recessed a second distance in the second direction (direction Y) away from the drain region 310, where the second distance is different than the first distance.

Still further, while FIG. 3A illustrates the recess of the gate 322 aligning with respect to top and bottom borders between non-step-dielectric regions 313 and step-dielectric regions 315 in the first direction (direction X, e.g., width direction), in other examples, the recess in one or more of non-step-dielectric regions 313 may be greater or less than the width of the non-step-dielectric region 313, e.g., by design. Also, even when the width of the recess is substantially the same as the width of the non-step-dielectric region 313, one border (e.g., top) may be covered by the gate 322 while the other border (e.g., bottom) may not be covered by the gate 322, e.g., by process non-uniformity/imperfection causing an offset (e.g., vertical shift of the gate 322 with respect to the borders already present). Additional features of the LDMOS device 300 shown in FIG. 3A, as well as some features not expressly shown, are described below.

FIG. 3B shows a first cross-sectional view of the LDMOS device 300 taken along the cut line shown in FIG. 3A in the second direction (direction Y) across one of the non-step-dielectric regions 313 where the gate 322 is recessed in the second direction (direction Y) away from the drain region 310. FIG. 3C shows a second cross-sectional view of the LDMOS device 300 taken along the cut line shown in FIG. 3A in the second direction (direction Y) across one of the step-dielectric regions 315. As shown in FIGS. 3B and 3C, a distance D1 between the drain region 310 and the gate 322 in the non-step-dielectric region 313 is greater than a distance D2 between the drain region 310 and the gate 322 in the step-dielectric region 315. FIG. 3D shows a third cross-sectional view of the LDMOS device 300 taken along the cut line shown in FIG. 3A in the first direction (direction X) along the gate 322, showing where portions of the gate 322 are recessed in the second direction (direction Y) away from the drain region 310. As such, FIG. 3D illustrates lack of the gate 322 in the corresponding non-step-dielectric regions 313. FIG. 3E shows a fourth cross-sectional view of the LDMOS device 300 taken along the cut line shown in FIG. 3A in the first direction (direction X) along the gate 322 where the gate 322 is continuous (e.g., not recessed along the cutline) in the second direction (direction Y) away from the drain region 310.

The LDMOS device 300 includes a substrate 302, a first buried layer 304, a second buried layer 306, a semiconductor layer 308 (or an epi layer 308), the drain region 310, a drain drift region 312, the source region 314, a well region 316, a first insulator layer 318, a second insulator layer 320, the gate 322, silicide layers 324, 326 and 328, ILD 330, and conductive vias 332, 334 and 336 which are disposed in a manner similar to that described above with respect to the substrate 102, the first buried layer 104, the second buried layer 106, the epi layer 108, the drain region 110, the drain drift region 112, the source region 114, the well region 116, the first insulator layer 118, the second insulator layer 120, the gate 122, the silicide layers 124, 126 and 128, the ILD 130, and the conductive vias 132, 134 and 136 of the LDMOS device 100, with the exception of the gate 322. As highlighted in FIGS. 3A, 3C, 3D and 3E, the gate 322 is recessed in the second direction (direction Y) away from the drain region 310 in the non-step-dielectric regions 313 but not in the step-dielectric regions 315. A channel region may be considered to extend across a portion of the epi layer 308 under gate 322 between the drain region 310 and the source region 314. While two buried layers, e.g., the first buried layer 304 and the second buried layer 306, are shown, other examples may include one or the other of the buried layers, or no buried layer at all.

Further, as shown in the example of FIGS. 3D and 3E, the gate 322 in the step-dielectric regions 315 terminates on an upper surface of the corresponding sections of the second insulating layer 320. In other examples, the gate 322 can terminate elsewhere on the upper surface, at the edges of the upper surface, or along the tapered sidewalls of the corresponding sections of the second insulating layer 320.

FIG. 3F shows a three-dimensional view of a portion of the LDMOS device 300. More particularly, FIG. 3F is a three-dimensional view from the perspective of a portion of the cross-sectional view of FIG. 3E without the ILD 330 shown.

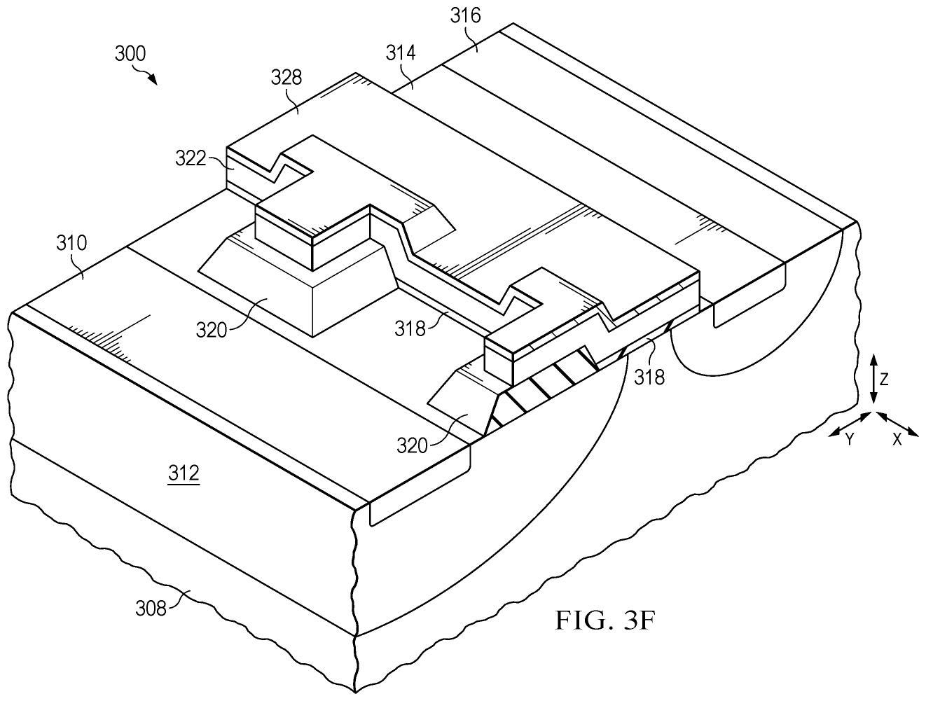

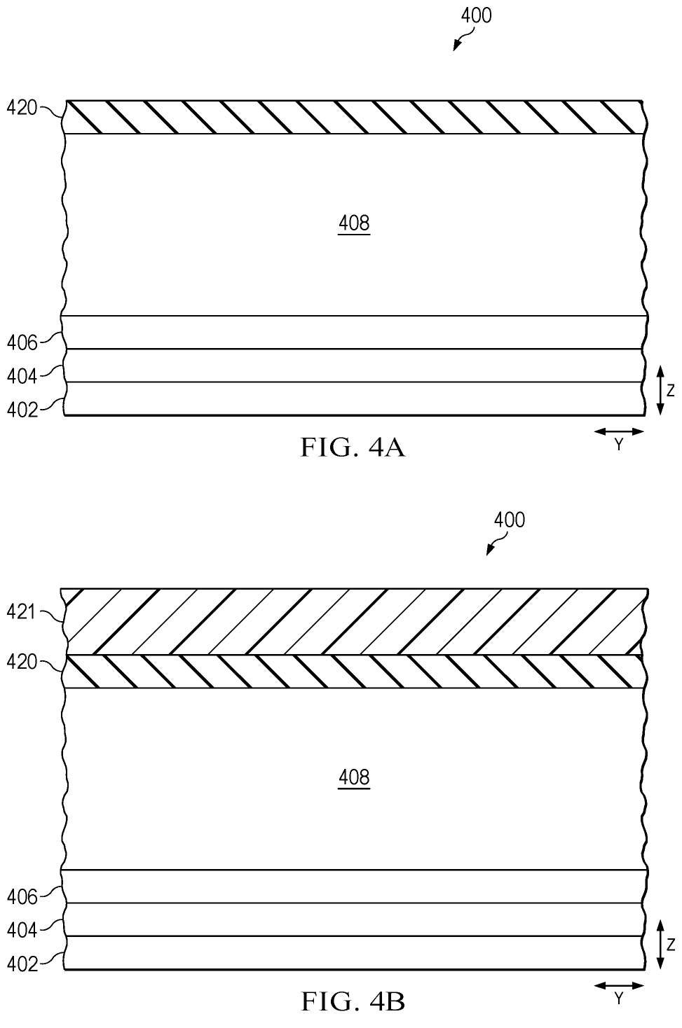

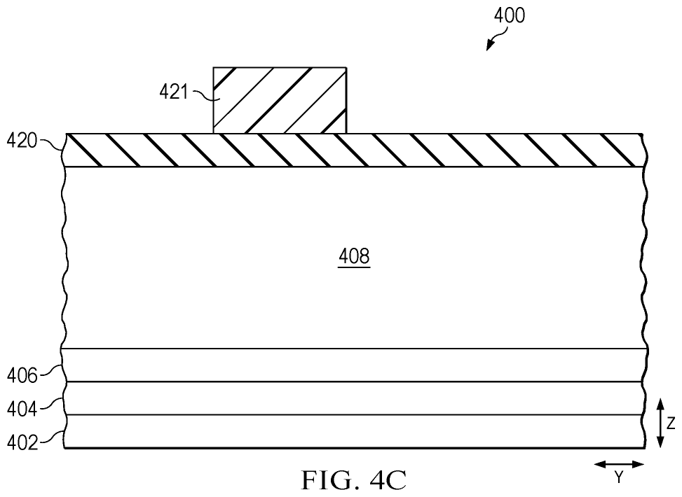

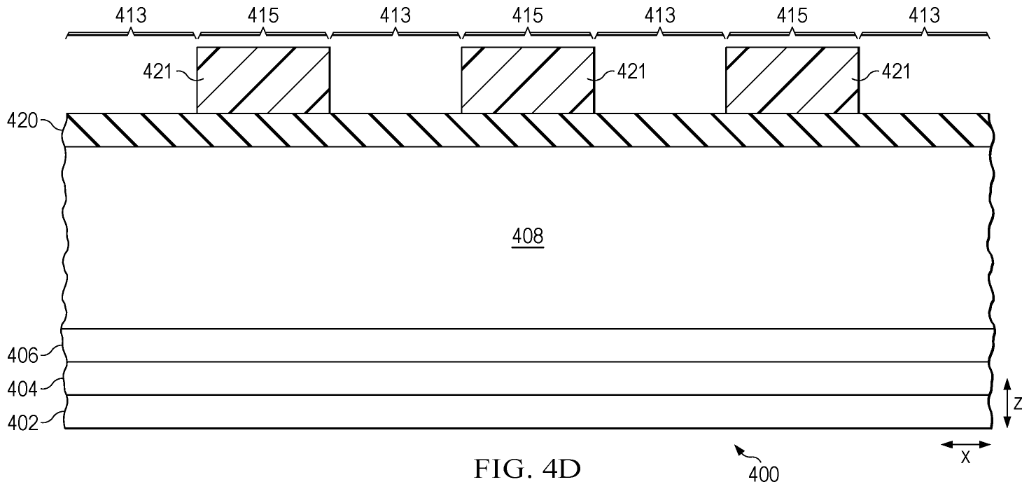

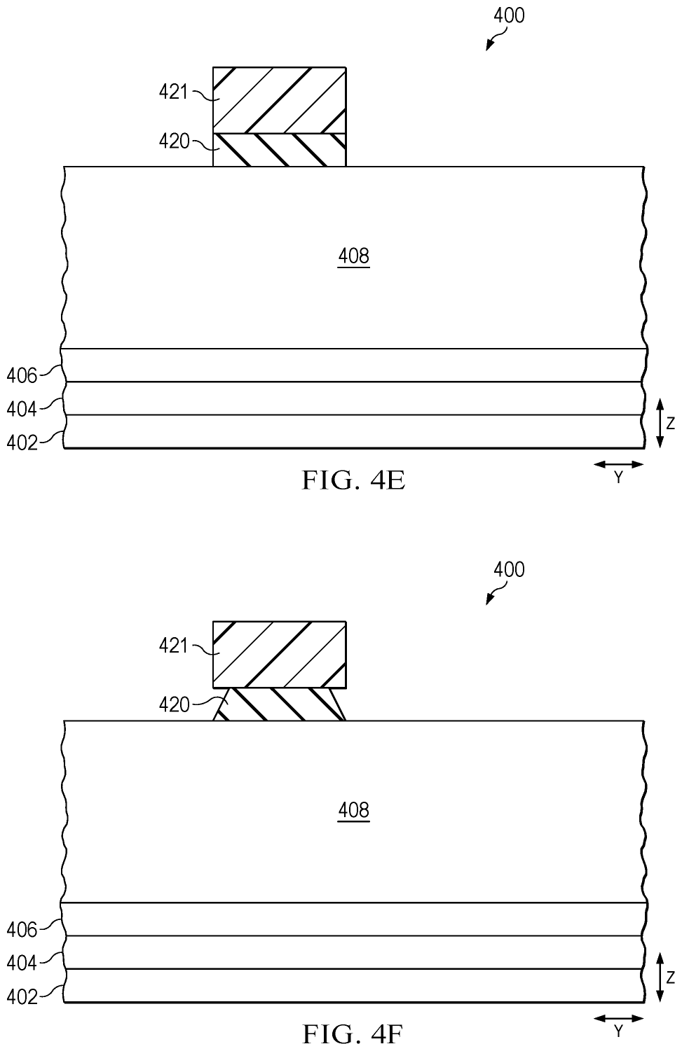

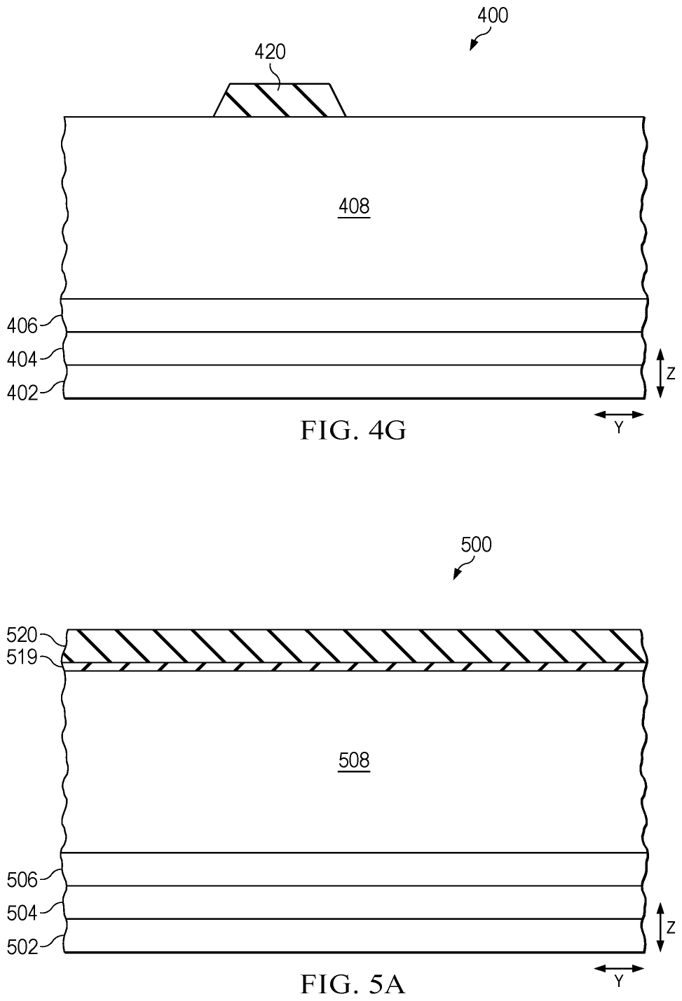

Process flows for forming a step-dielectric or field insulator, such as the second insulator layer 120, the second insulator layer 220 or the second insulator layer 320, will now be described with respect to FIGS. 4A-6I.

FIG. 4A shows a cross-sectional view of a structure 400 including a substrate 402, a first buried layer 404, a second buried layer 406 and a semiconductor layer 408 (or an epi layer 408), which are similar to the substrates 102, 202 and 302, the first buried layers 104, 204 and 304, the second buried layers 106, 206 and 306 and the epi layers 108, 208 and 308 described above with respect to the LDMOS devices 100, 200 and 300, respectively. An insulator layer 420 is blanket deposited over the epi layer 408 as shown, where the insulator layer 420 will later be patterned such that the insulator layer 420 is removed in non-step-dielectric regions 413 (shown in FIG. 4D) and remains in step-dielectric regions 415 (shown in FIG. 4D), which alternate in a first direction (direction X shown in FIG. 4D). The insulator layer 420 may have a thickness (in direction Z) sirnilar to that of the second insulating layer 120 of the LDMOS device 100. In the description below, it is assumed that the substrate 402, the second buried layer 406 and the epi layer 408 are p-type conductivity, and that the first buried layer 404 is n-type conductivity. Thus, in the description below, the substrate 402 may be referred to as a p-type substrate 402, the first buried layer 404 may be referred to as an n-type buried layer (NBL) 404, the second buried layer 406 may be referred to as a p-type buried layer (PBL) 406, and the epi layer 408 may be referred to as a lightly-doped p-type epi layer 408. In other examples, the conductivities may be reversed.

To form the NBL 404, the lightly-doped p-type epi layer 408 is grown over the p-type substrate 402, and a portion of the lightly-doped p-type epi layer 408 is processed (e.g., by dopant implantation) to form the NBL 404. The lightly-doped p-type epi layer 408 serves as a body region of the LDMOS device, and thus may be referred to as a body region 408. The p-type substrate 402 and the lightly-doped p-type epi layer 408 can both include silicon, and can also include other materials. The PBL 406 is formed using a high energy p-type implant to add doping to portions of the lightly-doped p-type epi layer 408. The p-type implant can be boron at a dose from 1×10¹² cm⁻² to 1×10¹³ cm⁻² at an energy of 400 keV to 3 mega-electron volts (MeV). Indium may also be used as the implant species. For low voltage (e.g., 20 V) versions of an LDMOS transistor, the p-type implant used for forming the PBL 406 can be a blanket implant, while for higher voltage (e.g., >30V) versions of an LDMOS device, the p-type implant for forming the PBL 406 can be a masked implant to allow selective placement. For the masked implant, a photomask (not specifically shown) is deposited and patterned with an opening which exposes regions of the lightly-doped p-type epi layer 408 where the p-type implant is to be performed in order to form the PBL 406 (e.g., a localized PBL 406). While the NBL 404 and PBL 406 are shown in FIGS. 4A-4G, the NBL 404 and PBL 406 are optional for building an LDMOS device (e.g., examples can include both as shown, one or the other, or no buried layer at all).

The insulator layer 420 is blanket deposited over the lightly-doped p-type epi layer 408. The insulator layer 420 is a dielectric material such as an oxide material. As shown in FIG. 4B, a mask layer 421 may be blanket deposited over the insulator layer 420. In some examples, the mask layer 421 is formed of a light sensitive organic material. The mask layer 421 is then patterned as shown in FIGS. 4C and 4D to cover portions of the insulator layer 420 where a step-dielectric or field insulator is to be formed. As shown in FIG. 4D, this includes patterning the mask layer 421 such that the mask layer 421 remains in the step-dielectric regions 415 and is removed in the non-step-dielectric regions 413.

As shown in FIG. 4E, the portions of the insulator layer 420 exposed by the patterned mask layer 421 are then removed using a suitable etch process. As shown in FIG. 4F, the remaining portions of the insulator layer 420 are then further etched to form tapered sidewalls. In other examples, the tapered sidewalls of the insulator layer 420 can be formed in the same etch process of FIG. 4E.

The patterned mask layer 421 is then removed as shown in FIG. 4G, resulting in sections of the insulator layer 420 in the step-dielectric regions 415 that alternate with the non-step-dielectric regions 413 in the first direction (direction X). The sections of the insulator layer 420 correspond to the step-dielectric sections of insulating layers 120, 220 and 320 described above with respect to the LDMOS devices 100, 200 and 300, respectively. Note that since FIGS. 4A-4G focus on the formation of the insulator layer 420 in the step-dielectric regions 415, a gate dielectric or a gate insulator layer similar to the first insulating layer 118 of FIG. 1D formed in the non-step-dielectric regions 413 is not expressly shown.

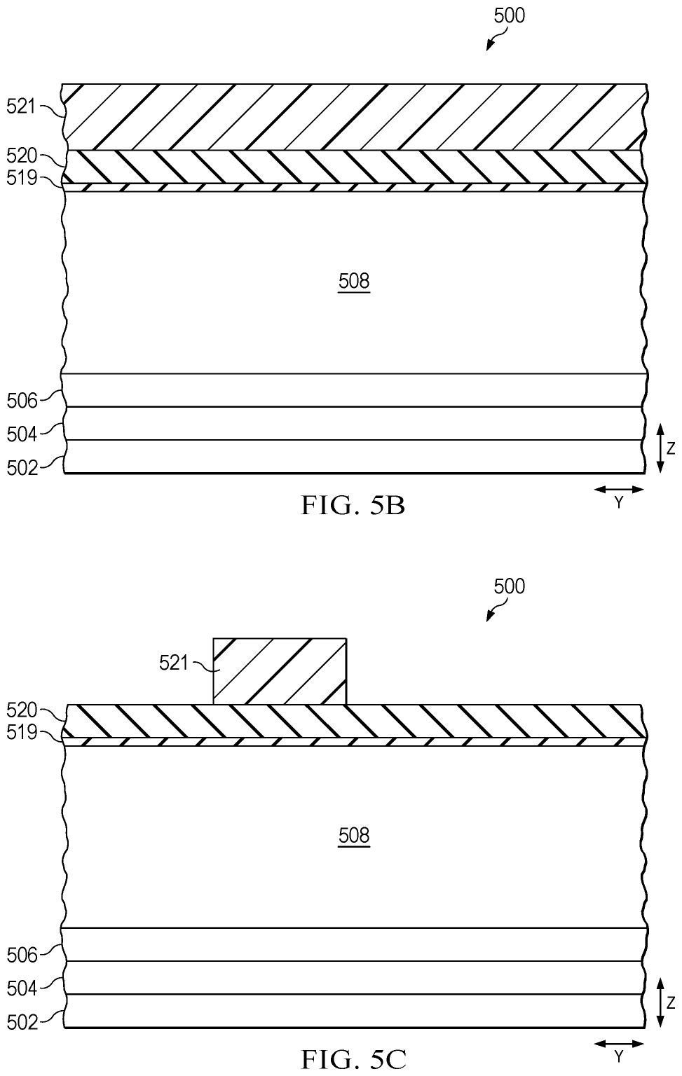

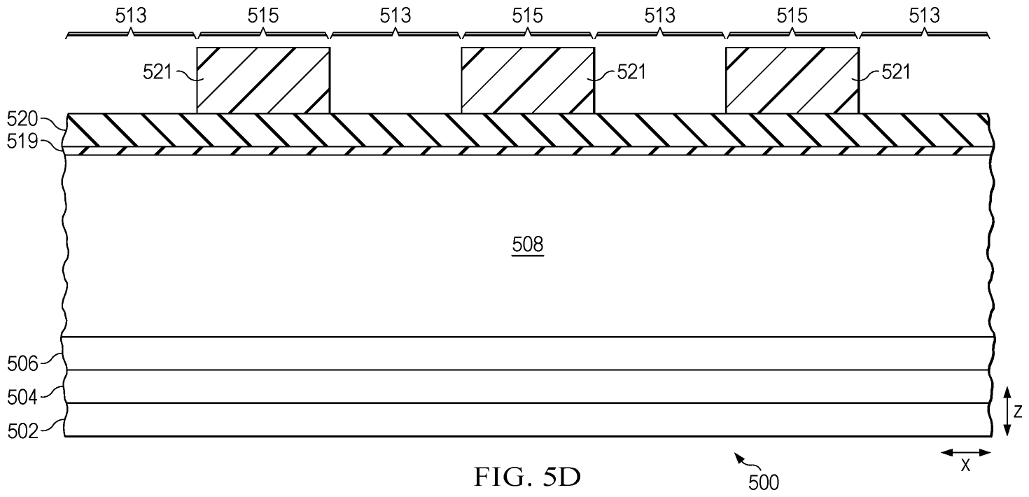

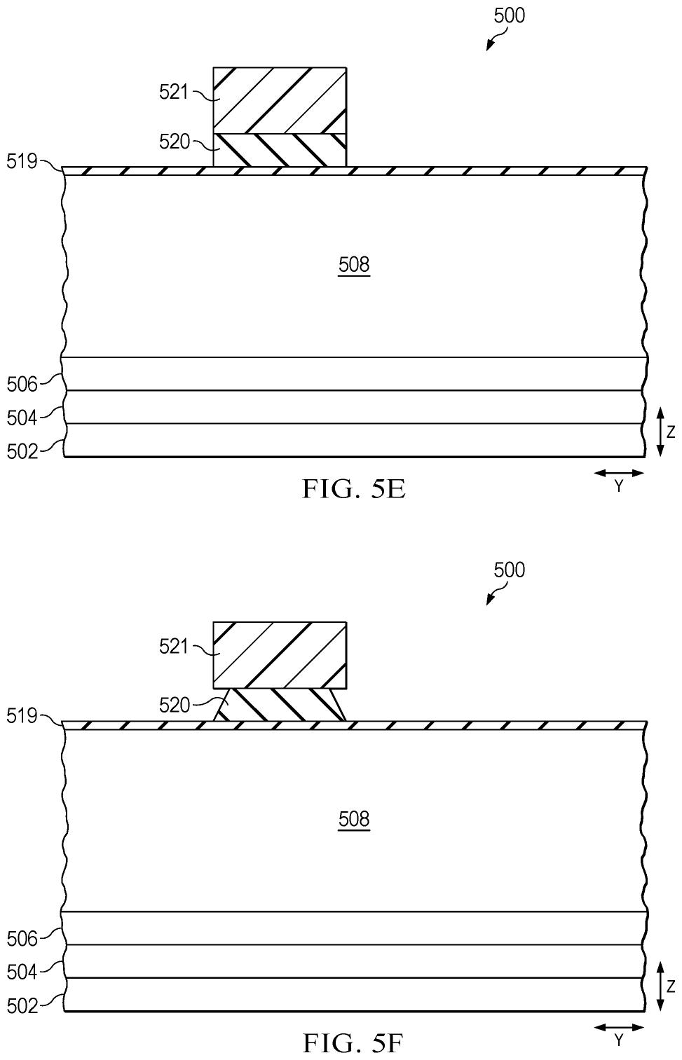

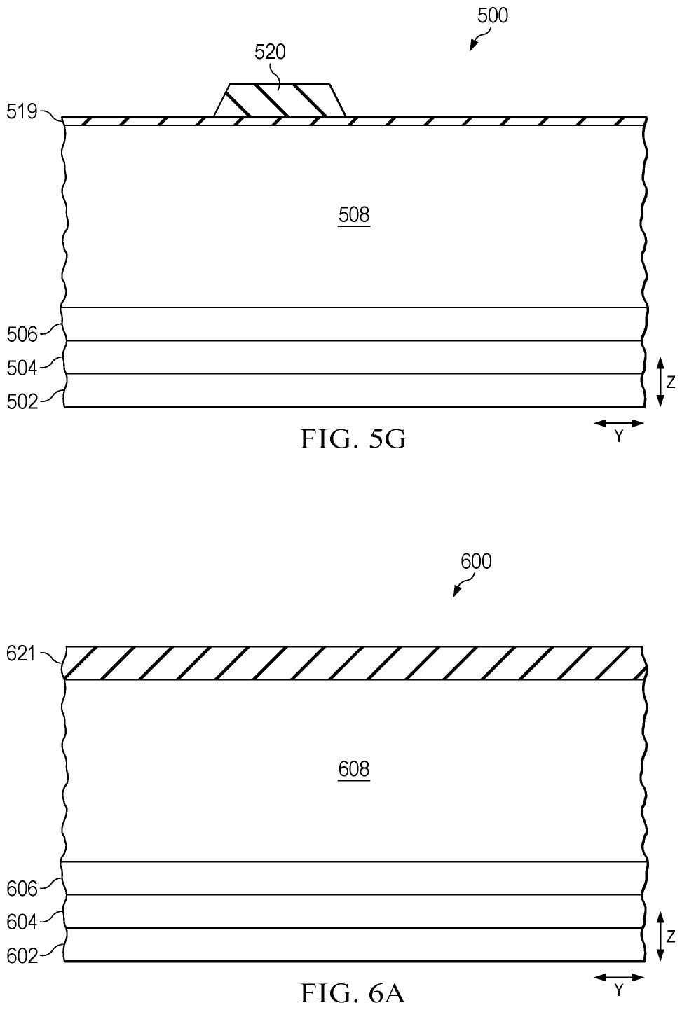

FIG. 5A shows a cross-sectional view of a structure 500 including a substrate 502, a first buried layer 504, a second buried layer 506 and an epi layer 508, which are similar to the substrates 102, 202 and 302, the first buried layers 104, 204 and 304, the second buried layers 106, 206 and 306, and the epi layers 108, 208 and 308 described above with respect to the LDMOS devices 100, 200 and 300, respectively. An interfacial oxide layer 519 is blanket deposited over the epi layer 508, followed by blanket deposition of a nitride-based insulator layer 520 over the interfacial oxide layer 519. The interfacial oxide layer 519 is a thin layer which facilitates adhesion of the nitride-based insulator layer 520 to the underlying structure (or mitigates stress between the nitride-based insulator layer 520 and the epi layer 508). The nitride-based insulator layer 520 will be patterned such that the nitride-based insulator layer 520 is removed in non-step-dielectric regions 513 (shown in FIG. 5D) and remains in step-dielectric regions 515 (shown in FIG. 5D), which alternate in a first direction (direction X shown in FIG. 5D). In the description below, it is assumed that the substrate 502, the second buried layer 506 and the epi layer 508 are p-type conductivity, and that the first buried layer 504 is n-type conductivity. Thus, in the description below, the substrate 502 may be referred to as a p-type substrate 502, the first buried layer 504 may be referred to as an NBL 504, the second buried layer 506 may be referred to as a PBL 506, and the epi layer 508 may be referred to as a lightly-doped p-type epi layer 508. In other examples, the conductivities may be reversed.

The NBL 504, the PBL 506 and the lightly-doped p-type epi layer 508 are formed in a manner similar to that described above with respect to the NBL 404, the PBL 406 and the lightly-doped p-type epi layer 408. The NBL 504 and PBL 506, similar to the NBL 404 and the PBL 406, are optional layers (e.g., examples can include both as shown, one or the other, or no buried layer at all).

The interfacial oxide layer 519 is an oxide material blanket deposited over the lightly-doped p-type epi layer 508. The nitride-based insulator layer 520 is blanket deposited over the interfacial oxide layer 519, and may have a thickness (in direction Z) similar to that of the insulator layer 420. The nitride-based insulator layer 520 is a nitride material.

As shown in FG 5B, a mask layer 521 may be blanket deposited over the nitride-based insulator layer 520. The mask layer 521 is formed of materials similar to that of the mask layer 421. The mask layer 521 is then patterned as shown in FIGS. 5C and 5D to cover portions of the nitride-based insulator layer 520 where a step-dieecttric or field insulator is to be formed. As shown in FIG. 5D, this includes patterning the mnask layer 521 such that the mask layer 521 remains in the step-dielectric regions 515 and is removed in the non-step-dielectric regions 513.

As shown in FIG. 5E, the portions of the nitride-based insulator layer 520 exposed by the patterned mask layer 1 are then removed using a suitable etch process.

As shown in FIG. 5F, the remaining portions of the nitride-based insulator layer 520 are then further etched to form tapered sidewalls. The patterned mask layer 521 is then removed as shown in FIG. 5G, resulting in sections of the nitride-based insulator layer 520 in the step-dielectric regions 515 that alternate with the non-step-dielectric regions 513 in the first direction (direction X). The sections of the nitride-based insulator layer 520 correspond to the step-dielectric sections of insulating layers 120, 220 and 320 described above with respect to the LDMOS devices 100, 200 and 300, respectively. Note that since FIGS. 5A-5G focus on the formation of the nitride-based insulator layer 520 in the step-dielectric regions 515, a gate dielectric or a gate insulator layer similar to the first insulating layer 118 of FIG. 1D formed in the non-step-dielectric regions 513 is not expressly shown.

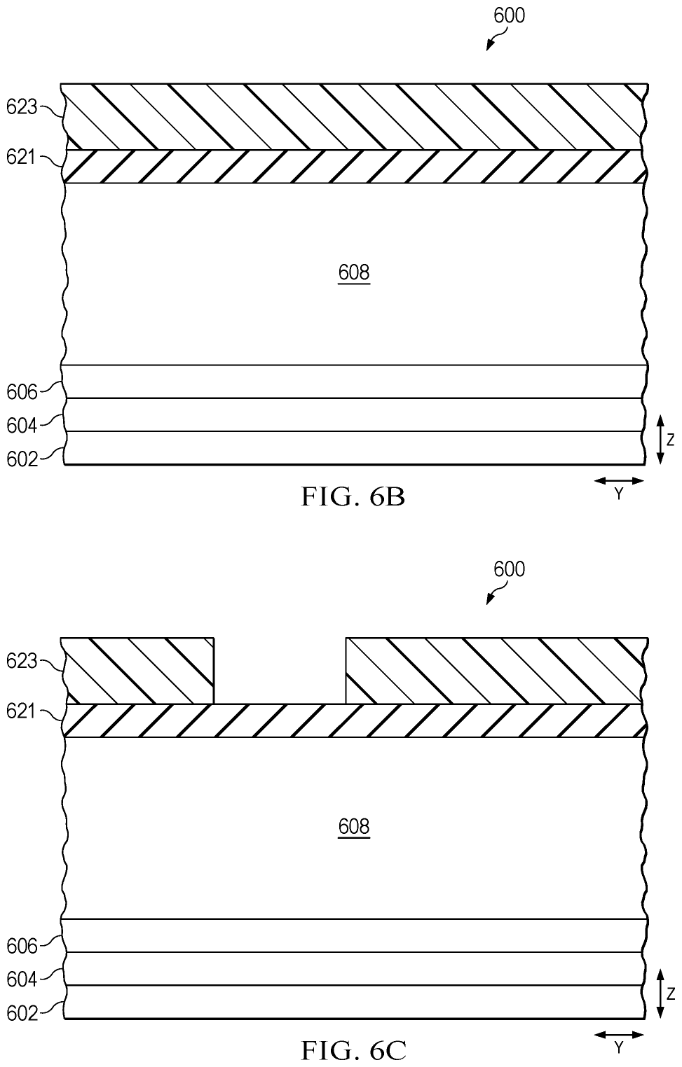

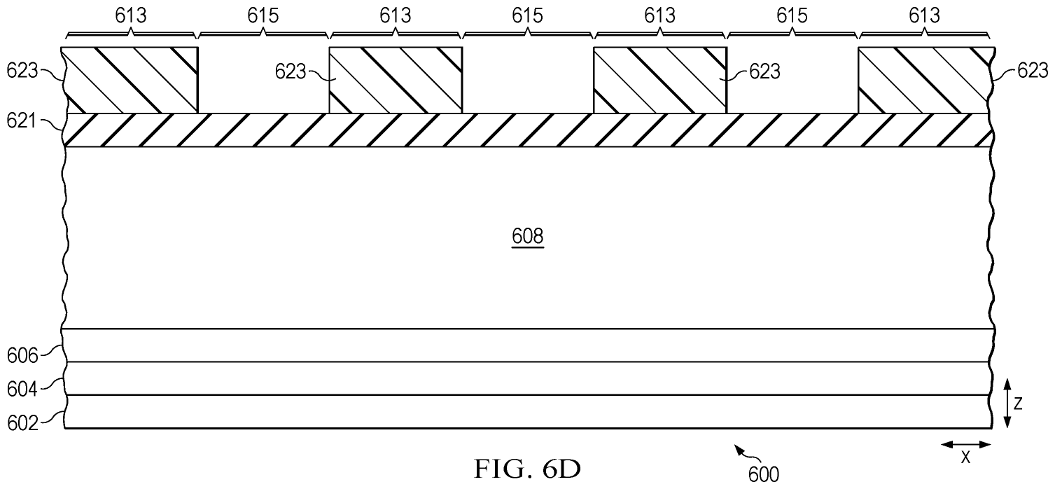

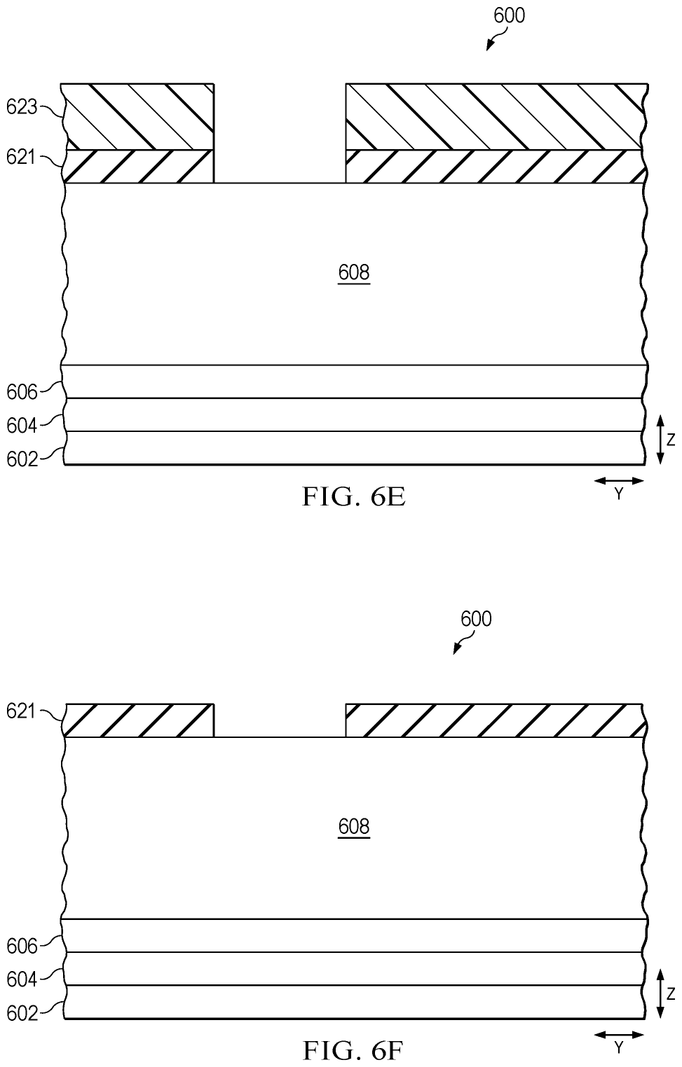

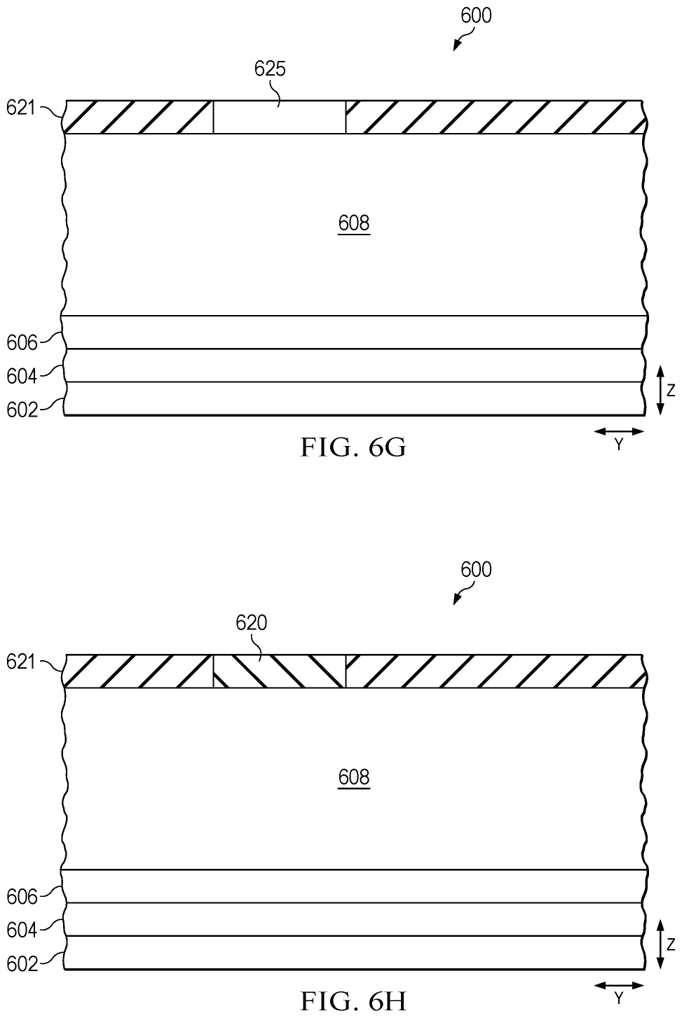

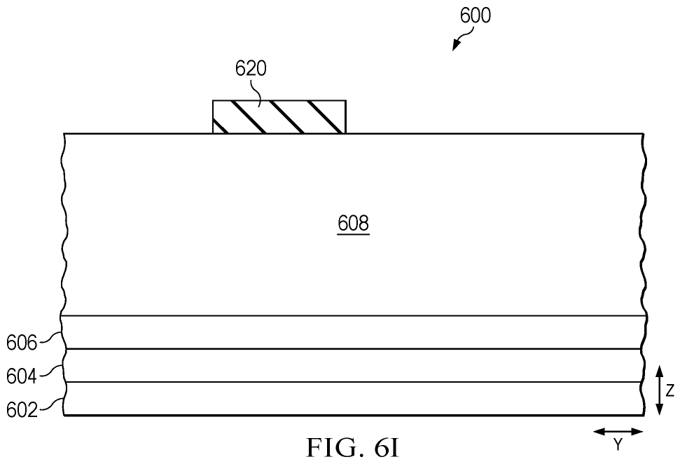

FIG. 6A shows a cross-sectional view of a structure 600 including a substrate 602, a first buried layer 604, a second buried layer 606 and an epi layer 608, which are similar to the substrates 102, 202 and 302, the first buried layers 104, 204 and 304, the second buried layers 106, 206 and 306, and the epi layers 108, 208 and 308 described above with respect to the LDMOS devices 100, 200 and 300, respectively. In the description below, it is assumed that the substrate 602, the second buried layer 606 and the epi layer 608 are p-type conductivity, and that the first buried layer 604 is n-type conductivity. Thus, in the description below, the substrate 602 may be referred to as a p-type substrate 602, the first buried layer 604 may be referred to as an NBL 604, the second buried layer 606 may be referred to as a PBL 606, and the epi layer 608 may be referred to as a lightly-doped p-type epi layer 608. In other examples, the conductivities may be reversed.

The NBL 604, the PBL 606 and the lightly-doped p-type epi layer 608 are formed in a manner similar to that described above with respect to the NBL 404, the PBL 406 and the lightly-doped p-type epi layer 408. The NBL 604 and PBL 606, similar to the NBL 404 and the PBL 406, are optional layers (e.g., examples can include both as shown, one or the other, or no buried layer at all).

A nitride layer 621 is blanket deposited over the lightly-doped p-type epi layer 608 as shown in FIG. 6A. A thickness (in direction Z) of the nitride layer 621 corresponds to a desired thickness of resulting step-dielectric or field insulators that are to be formed. As shown in FIG. 6B, a mask layer 623 (e.g., a photomask) is formed over the nitride layer 621.

As shown in FIGS. 6C and 6D, the mask layer 623 is patterned to expose portions of the nitride layer 621 where the step-dielectric or field insulator is to be formed. FIG. 6D shows how the mask layer 623 is patterned in the first direction (direction X) so as to enable formation of alternating non-step-dielectric regions 613 and step-dielectric regions 615.

As shown in FIG. 6E, portions of the nitride layer 621 exposed by the patterned mask layer 623 are then removed using a suitable etch process. The patterned mask layer 623 is then removed as shown in FIG. 6F. An epitaxial layer 625 is then selectively grown over portions of the lightly-doped p-type epi layer 608 exposed by the patterned nitride layer 621 as shown in FIG. 6G. The epitaxial layer 625 is then subject to an oxidation process to form insulator layer 620 as shown in FIG. 6H. The nitride layer 621 is then removed as shown in FIG. 6I. Although not shown, the insulator layer 620 may be subjected to further etching to form tapered sidewalls. The sections of the insulator layer 620 correspond to the step-dielectric sections of insulating layers 120, 220 and 320 described above with respect to the LDMOS devices 100, 200 and 300, respectively. Note that since FIGS. 6A-6I focus on the formation of the insulator layer 620 in the step-dielectric regions 615, a gate dielectric or a gate insulator layer similar to the first insulating layer 118 of FIG. 1D formed in the non-step-dielectric regions 613 is not expressly shown.

The processing steps forming the step-dielectric sections shown in FIGS. 4G, 5G and 6I (which may be referred to as a step-dielectric process module hereinafter) may be integrated with other processing steps to form additional portions of an LDMOS device to result in one of the LDMOS devices 100, 200 and 300 described above. In some examples, the step-dielectric process module may be added after forming STI regions, e.g., including the STI regions 238 described with reference to FIGS. 2A through 2E. Subsequently, additional processing steps may be performed, e.g., forming a drain drift region (e.g., drain drift region 112, drain drift region 212 or drain drift region 312), forming a well region (e.g., well region 116, well region 216 or well region 316), forming a gate insulator (e.g., first insulator layer 118, first insulator layer 218 or first insulator layer 318), forming a gate (e.g., gate 122, gate 222 or gate 322), forming gate spacers (not specifically shown), forming a drain region (e.g., drain region 110, drain region 210 or drain region 310) and a source region (e.g., source region 114, source region 214 or source region 314), forming silicide layers (e.g., silicide layers 124, 126 and 128, silicide layers 224, 226 and 228, or silicide layers 324, 326 and 328), forming ILD (e.g., ILD 130, ILD 230 or ILD 330), and forming conductive vias (e.g., conductive vias 132, 134 and 136, conductive vias 232, 234 and 236, or conductive vias 332, 334 and 336).

In other examples, the step-dielectric process module may be added after forming STI regions as well as additional implants forming various drift and well regions in the semiconductor layer (e.g., epi layer 108, 208, 308), prior to forming a gate insulator (e.g., first insulator layer 118, first insulator layer 218 or first insulator layer 318) and a gate (e.g., gate 122, gate 222 or gate 322) on the gate insulator. After forming the gate stack including the gate insulator and the gate, additional process steps may be performed, e.g., forming gate spacers (not specifically shown), forming a drain region (e.g., drain region 110, drain region 210 or drain region 310) and a source region (e.g., source region 114, source region 214 or source region 314), forming silicide layers (e.g., silicide layers 124, 126 and 128, silicide layers 224, 226 and 228, or silicide layers 324, 326 and 328), forming ILD (e.g., ILD 130, ILD 230 or ILD 330), and forming conductive vias (e.g., conductive vias 132, 134 and 136, conductive vias 232, 234 and 236, or conductive vias 332, 334 and 336). Certain aspects of the process flow for forming such additional portions will now be described.

In some examples, a drain drift region (e.g., drain drift region 112, drain drift region 212 or drain drift region 312) is formed in a semiconductor layer (e.g., epi layer 108, epi layer 208 or epi layer 308) by performing one or more masked implantation steps, e.g., by forming a drain drift mask layer (or a photomask). In some examples, an implant to form the drain drift region occurs in two steps (e.g., a first implantation process with a first energy and a first dose followed by a second implantation process with a second energy and a second dose). In some examples, the first implantation process implants phosphorous dopants at the first energy of 20-40 kilo-electron volts (keV) and the first dose of 2-8×10¹² cm⁻² In some examples, the first implantation process implants phosphorus dopants at the first energy of 20-40 kV for an oxide thickness of 70-110 nanometers (nm). In some examples, the first dose is 2-5×10¹² cm⁻². The second implantation process uses the same drain drift mask layer to implant the same region of the semiconductor layer. In some examples, the second energy is greater than the first energy. In some examples, the second implantation process implants phosphorus dopants at the second energy of 70-350 keV and the second dose of 2-5×10¹² cm⁻². In some examples, the second implantation process implants phosphorus dopants at the second energy less than or equal to 150 keV. In some examples, the second implantation process implants phosphorus dopants at the second energy greater than or equal to 100 keV, such as 100-350 keV. In some examples, the second implantation process includes more than one implant, such as an implantation at 120 keV and another implantation at 250 keV.

Following formation of the drain drift region, the drain drift mask layer is removed and a well region mask layer is patterned over the semiconductor layer to expose portions of the semiconductor layer where the well region (e.g., well region 116, well region 216 or well region 316) is to be formed. An implantation process is then performed to implant p-type dopants within the exposed areas of the semiconductor layer to form the well region. The p-type dopants may include boron. Besides boron, the p-type dopants can include indium. Indium, being a relatively large atom, has the advantage of a low diffusion coefficient relative to boron. In the case of a boron implant, the implantation process uses a dose sufficient to enable formation of a channel laterally and to suppress body NPN effects during operation of an LDMOS device. For example, a boron implant with an energy of 20 keV, a dose of 8×10¹³ cm⁻² to 3.0×10¹⁴ cm⁻², such as 1.5×10¹⁴ cm², and a tilt angle of less than 5 degrees, such as 2 degrees, may be used. The well region mask layer may then be removed after the implantation process.

The gate insulator (e.g., first insulating layer 118, first insulating layer 218 or first insulating layer 318) and the gate (e.g., gate 122, gate 222 or gate 322) may be formed over the structure through deposition and patterning using one or more gate masking layers. In some examples, a gate insulator material is formed using a high temperature furnace operation or a rapid thermal process. The gate insulator material may have a thickness in the range of approximately 3 nm to 15 nm. Gate material is then deposited over the gate insulator. In some examples, the gate material is deposited using a gate deposition process using any of a number of silane-based precursors. Polycrystalline silicon is one example of a material for the gate, however, a metal gate or a CMOS-based replacement gate process can also be used to form the gate.

After deposition of the gate insulator material and the gate material, a gate masking layer may be formed over the gate material and the underlying gate insulator material where the final gate and gate insulator should remain. Portions of the gate insulator material and the gate material which are exposed by the one or more gate masking layers are then removed (e.g., using a plasma etch or other suitable etch process) to define the final gate and gat insulator, and the one or more gate masking layers are then removed. In examples where the final gate is to be recessed in non-step-dielectric regions (e.g, regions 413 shown in FIG. 4D), the gate masking layer is suitably patterned in the first direction (direction X) to achieve the desired recess of the gate in such regions. In some examples, lightly doped drain regions are formed after patterning the gates, e.g., implanting n-type dopant species self-aligned at the edge of patterned gates. Subsequently, gate spacers may be formed on the sidewalls of the patterned gates.

In some examples, forming the gate spacers may be followed by formation of a drain/source mask layer that exposes portions of the drain drift region (e.g., drain drift region 112, drain drift region 212 or drain drift region 312) and the well region (e.g., well region 116, well region 216 or well region 316) where the drain region (e.g., drain region 110, drain region 210 or drain region 310) and the source region (e.g., source region 14, source region 214 or source region 314) are to be formed, respectively, An implantation process is then performed to implant n-type dopants within the exposed areas of the drain drift region and the well region to form the drain region and the source region. The drain/source mask layer is then removed.

After forming the source and drain regions, the silicide layers (e.g., silicide layers 124, 126 and 128, silicide layers 224, 226 and 228, or silicide layers 324, 326 and 328) are then formed over the drain region, the source region and the gate. In some examples, the silicide layers are formed by forming a metal layer, which forms a metal silicide at temperatures consistent with silicon processing conditions, followed by heating of the structure to form a metal silicide. Unreacted portions of the metal layer are then removed, such as using a wet stripping process.

The ILD (e.g., ILD 130, ILD 230 or ILD 330) is then deposited over the structure. The ILD is formed of a dielectric material. A contact masking layer is then formed over the ILD to expose regions of the ILD where the conductive vias (e.g., conductive vias 132, 134 and 136, conductive vias 232, 234 and 236, or conductive vias 332, 334 and 336) are to be formed. Exposed regions of the ILD are then removed, followed by filling of the conductive vias, followed by removal of the contact masking layer. The conductive vias are formed of a suitable metal such as tungsten. Additional metal interconnects may be formed as desired to construct a metal interconnect system for the structure.

In examples where STI regions (e.g., STI regions 238) are to be formed, the STI regions may be formed prior to formation of the step-dielectric or field insulator (e.g., prior to formation of the insulator layer 420 in FIG. 4A, prior to formation of the interfacial oxide layer 519 in FIG. 5A, or prior to formation of the nitride layer 621 in FIG. 6A). To do so, an STI masking layer is formed over the semiconductor layer (e.g., the lightly-doped p-type epi layer 408, 508 or 608) followed by removal of portions of the p-type epi layer exposed by the STI masking layer and depositing of an STI material to form the STI regions.

While FIGS. 4A-4G, 5A-5G and 6A-6I show process flow for formation of step-dielectric or field insulators prior to formation of a drain region (e.g., drain region 110, drain region 210 or drain region 310), a drain drift region (e.g., drain drift region 112, drain drift region 212 or drain drift region 312), a source region (e.g., source region 114, source region 214 or source region 314), and a well region (e.g., well region 116, well region 216 or well region 316), this by way of example only.

In other examples, the step-dielectric or field insulator may be formed subsequent to formation of a drain region, a drain drift region, a source region and a well region. Further, step-dielectrics or field insulators may be formed using various other types of processing other than that shown in FIGS. 4A-6I. In some examples, the step-dielectric or field insulator is thermally grown using local oxidation of silicon (LOCOS) processing to form a layer of silicon dioxide with tapered ends over a silicon layer (e.g., epi layer 108, epi layer 208 or epi layer 308).

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a drain region disposed in the semiconductor layer;
a source region disposed in the semiconductor layer;
a channel region disposed between the drain region and the source region;
a gate disposed over the channel region; and
first and second insulating layers disposed between the gate and the semiconductor layer, wherein sections of the first insulating layer and sections of the second insulating layer alternate along a first direction perpendicular to a second direction defined between the drain region and the source region, each of the sections of the first insulating layer having a first thickness and each of the sections of the second insulating layer having a second thickness greater than the first thickness.

2. The semiconductor device of claim 1, wherein the second insulating layer comprises an oxide material.

3. The semiconductor device of claim 1, wherein the second insulating layer comprises a nitride material.

4. The semiconductor device of claim 1, wherein each of the sections of the second insulating layer comprises tapered sidewalls.

5. The semiconductor device of claim 1, further comprising:
trench insulating sections disposed in the semiconductor layer and in alignment, in the first direction, with the sections of the first insulating layer.

6. The semiconductor device of claim 5, wherein the trench insulating sections comprise shallow trench isolation regions.

7. The semiconductor device of claim 1, wherein the gate comprises recessed portions in alignment with the sections of the first insulating layer.

8. The semiconductor device of claim 7, wherein the recessed portions extend in the second direction.

9. The semiconductor device of claim 1, wherein the semiconductor device comprises a laterally-diffused metal-oxide semiconductor (LDMOS) transistor.

10. A semiconductor device, comprising:
a semiconductor layer;
a drain region disposed in the semiconductor layer;
a source region disposed in the semiconductor layer;
a channel region disposed between the drain region and the source region;
a gate disposed over the channel region; and
gate dielectric and field dielectric layers disposed between the gate and the semiconductor layer, wherein sections of the gate dielectric layer and sections of the field dielectric layer alternate along a first direction perpendicular to a second direction defined between the drain region and the source region, each of the sections of the gate dielectric layer having a first thickness and each of the sections of the field dielectric layer having a second thickness greater than the first thickness.

11. The semiconductor device of claim 10, wherein the field dielectric layer comprises an oxide material.

12. The semiconductor device of claim 10, wherein the field dielectric layer comprises a nitride material.

13. The semiconductor device of claim 10, wherein each of the sections of the field dielectric layer comprises tapered sidewalls.

14. The semiconductor device of claim 10, further comprising:
trench insulating sections disposed in the semiconductor layer and in alignment, in the first direction, with the sections of the gate dielectric layer.

15. The semiconductor device of claim 10, wherein the gate comprises recessed portions in alignment with the sections of the gate dielectric layer and extending in the second direction.

16. The semiconductor device of claim 10, wherein the semiconductor device comprises a laterally-diffused metal-oxide semiconductor (LDMOS) transistor.

17. A method of fabricating a semiconductor device, comprising:
forming a semiconductor layer;
forming a drain region in the semiconductor layer;
forming a source region in the semiconductor layer;
forming a channel region between the drain region and the source region;
forming first and second insulating layers at least partially along the channel region and between the drain region and the source region, wherein sections of the first insulating layer and sections of the second insulating layer alternate along a first direction perpendicular to a second direction defined between the drain region and the source region, each of the sections of the first insulating layer having a first thickness and each of the sections of the second insulating layer having a second thickness greater than the first thickness; and
forming a gate on the first and second insulating layers.

18. The method of claim 17, wherein the second insulating layer is an oxide material, and wherein forming the second insulating layer comprises:
forming an oxide layer over the semiconductor layer;
forming a masking layer over the oxide layer;
patterning the masking layer to cover portions of the oxide layer where the sections of the second insulating layer are to be formed;
removing exposed portions of the oxide layer; and
removing the masking layer.

19. The method of claim 17, wherein the second insulating layer is an oxide material, and wherein forming the second insulating layer comprises:
forming a nitride layer over the semiconductor layer;
forming a masking layer over the nitride layer;
patterning the masking layer to expose portions of the nitride layer where the sections of the second insulating layer are to be formed;
removing exposed portions of the nitride layer to expose a surface of the semiconductor layer;
removing the masking layer;
growing an epitaxial layer over the exposed surface of the semiconductor layer;
oxidizing the epitaxial layer; and
removing remaining portions of the nitride layer.

20. The method of claim 17, wherein the second insulating layer is a nitride material, and wherein forming the second insulating layer comprise:
forming an interfacial oxide layer over the semiconductor layer;
forming a nitride layer over the interfacial oxide layer;
forming a masking layer over the nitride layer;
patterning the masking layer to cover portions of the nitride layer where the sections of the second insulating layer are to be formed;
removing exposed portions of the nitride layer; and
removing the masking layer.
